(19) United States
(12) Patent Application Publication
(10) Pub. No.: US 2007/0091551 A1
(43) Pub. Date: Apr. 26, 2007

(54) Computer keyboard capable of receiving and transmitting voice via internet

(76) Inventors: Siang-Hsiung Chen, Taipei City (TW); Min-Yung Hsu, Taipei City (TW)

Correspondence Address: LEONG C LEI, PMB # 1008, 1867 YGNACIO VALLEY ROAD, WALNUT CREEK, CA, 94598, US

(21) Appl. No.: 11/240,494

(22) Filed: Oct. 3, 2005

(51) Int. Cl. G06F 1/16; H05K 5/00; H05K 7/00

(52) U.S. Cl. 361/680

(57) ABSTRACT

A computer keyboard which includes a body portion, two loudspeakers mounted on the body portion, a microphone mounted on the body portion, a plurality of sockets mounted on the body portion, a switch mounted on the keyboard, a volume control mounted on the keyboard, a cable provided with a USB connector, a loudspeaker connector, a microphone connector, and a cable reel connected with the cable, whereby the computer keyboard can be used for converting electrical signals into sounds loud enough to be heard at a distance and converting sound waves into electrical energy thereby enabling the user to listen to the music and talk through the computer via the Internet.

### BACKGROUND OF THE INVENTION

1. Field of the Invention

This invention is related to a computer keyboard, and in particular to one which can be used for converting electrical signals into sounds loud enough to be heard at a distance and converting sound waves into electrical energy thereby enabling the user to listen to the music and talk through the computer via the Internet.

2. Description of the Prior Art

Many forms of keyboard are used or have been proposed for providing electrical outputs corresponding to the keys which have been operated. The electrical signal output may be provided for example by direct mechanical operation of contacts in an electrical circuit or by changing the inductance or capacitance in an electrical circuit or by use of magnetically operated switches, e.g. reed switches or Hall effect devices. Further, a standard keyboard with additional Hot Keys such as multimedia function control keys has been developed to match with the running of an application program of Win 95, so that the operator can directly operate these Hot Keys and monitor the operation through the display screen. Nevertheless, the user must buy loudspeakers and microphone in order to listen to music or the like and talk through the Internet thereby increasing the cost. Furthermore, the wires connecting the loudspeakers and microphone to the computer will make the desk a mess.

Therefore, it is an object of the present invention to provide a computer keyboard which can be used for converting electrical signals into sounds loud enough to be heard at a distance and converting sound waves into electrical energy thereby enabling the user to listen to the music and talk through the computer via the Internet.

### SUMMARY OF THE INVENTION

According to the present invention, there is provided a computer keyboard which includes a body portion, two loudspeakers mounted on the body portion, a microphone mounted on the body portion, a plurality of sockets mounted on the body portion, a switch mounted on the keyboard, a volume control mounted on the keyboard, a cable provided with a USB connector, a loudspeaker connector, a microphone connector, and a cable reel connected with the cable, the cable reel comprising an upper cover, a pad, a reeling disc, a spring, and a lower cover, the reeling disc and a positioning element being mounted at an inner edge of the lower cover to form an engaging and disengaging mechanism, wherein the positioning element includes a positioning shaft and a positioning plate and the positioning plate covers a top portion of the positioning shaft and is secured with a peg and the positioning plate has a pivot hole at a center thereof for a pivot mounting of the positioning shaft, and a front end of the positioning plate exposed from a shaft body of a positioning shaft is provided with a sliding protruded section corresponding to a railing slot at a bottom section of the reeling disc, and a bottom section is provided with a railing slot for the sliding protruded section to rotate along the reeling slot so as to provide an alternating engaging and a disengaging action.

It is the primary object of the present invention to provide a computer keyboard which can be used for converting electrical signals into sounds loud enough to be heard at a distance.

It is another object of the present invention to provide a computer keyboard which can be used for converting sound waves into electrical energy.

It is a further object of the present invention to provide a computer keyboard which enables a user to listen to the music and talk through the computer via the Internet. The foregoing objects and summary provides only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view of a computer keyboard according to the present invention;

FIG. 2 is a plan view of a transmission cable according to the present invention;

FIG. 3 is an exploded view of the cable reel according to the present invention;

FIG. 4 is an exploded view of the positioning shaft of the cable reel;

FIG. 5 is a schematic view of the positioning shaft of the cable reel; and

FIG. 6 is a sectional view of the positioning shaft of the cable reel.

### DETAILED DESCRIPTION OF THE PREFERRED EMBODIMENT

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

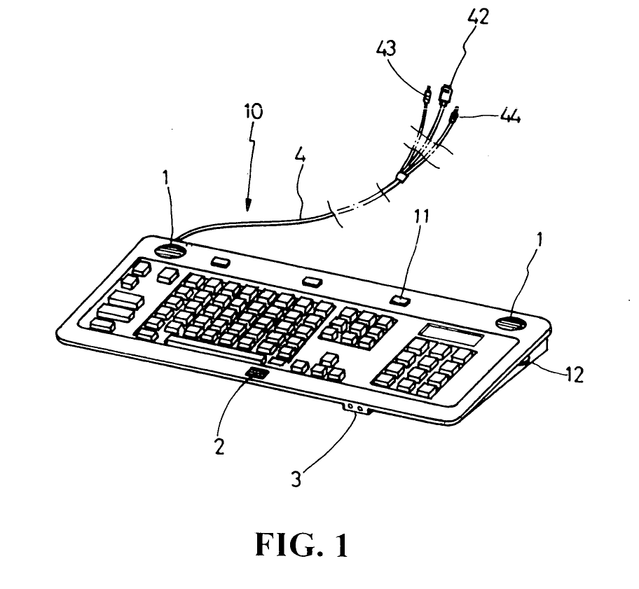

Referring to FIG. 1, the computer keyboard according to the present invention comprises a body portion (shown but not numbered) on which are mounted two loudspeakers 1, a microphone 2 and a plurality of sockets 3. The body portion of the computer keyboard is further provided with a switch 11 and a volume control 12. The switch 11, the volume control 12, the loudspeakers 1 and the sockets 3 are all connected to a circuit board (not shown) mounted within the computer keyboard. the loudspeakers 1 are mounted on the top of the computer keyboard, the microphone 2 is also arranged on the top of the computer keyboard, the switch 11 is installed between the two loudspeakers 1 on the top of the computer keyboard, and the volume control 12 is disposed at one side of the computer keyboard.

The microphone 2 is used for transmitting voice through a computer (not shown) via the Internet, while the loudspeakers 1 are used for reproducing voice from the computer via the Internet. Hence, the computer keyboard can be used for bidirectional communication through the computer via the Internet.

The switch 1 is used for making or breaking the connection of the microphone 2 with the computer. The volume control 12 is used for adjusting the magnitude of sound as desired. The sockets 3 are used for connecting a headphone (not shown) so that when the headphone is being used, the loudspeakers 11 will not give sound.

As shown in FIG. 1, the computer keyboard 1 is connected with the computer via a transmission cable 4 which comprises a USB connector 42, a loudspeaker connector 43, and a microphone connector 44.

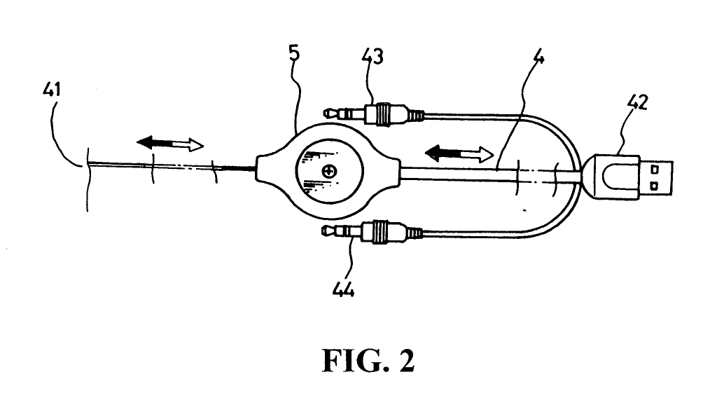

FIG. 2 illustrates another preferred embodiment of the transmission cable 4. As illustrated, the transmission cable 4 is connected with a cable reel 5 transmission cable 4 comprises a USB connector 42, a loudspeaker connector 43 and a microphone connector 44 which are connected with the keyboard connector (not shown), the loudspeaker connector (not shown) and the microphone connector (not shown) of the computer.

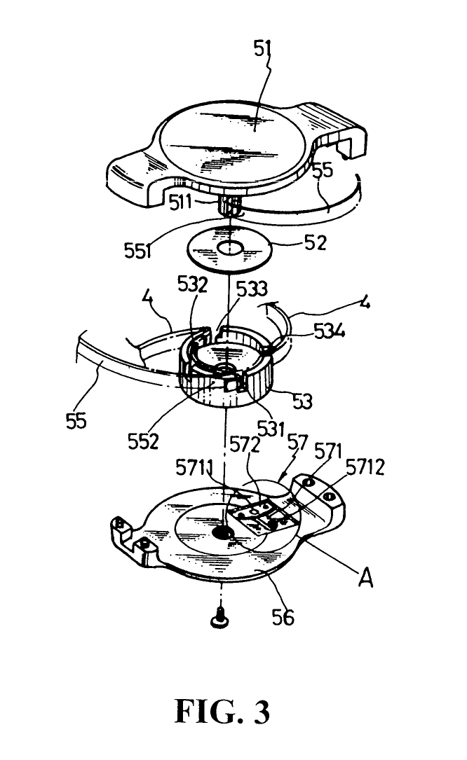

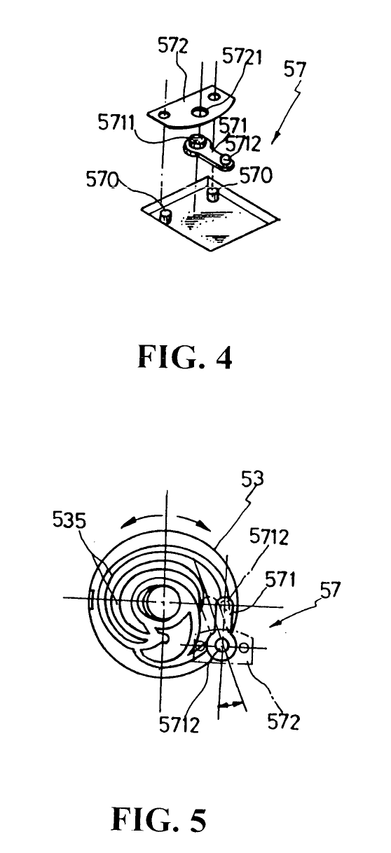

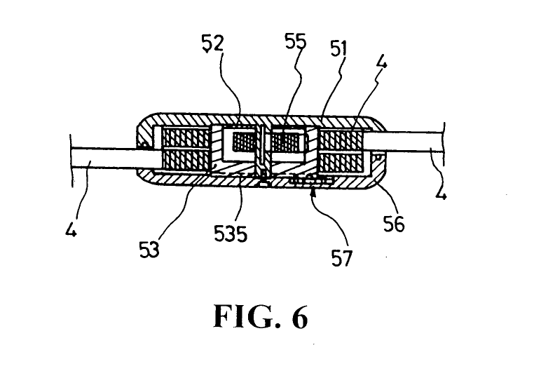

As can be seen in FIGS. 3, 4 and 5, the cable reel 5 of the present invention includes an upper cover 51, a pad 52, a reeling disc 53, a transmission cable 4, a spring 55, a lower cover 56, and a positioning element 57. The inner end 551 of the spring 55 is connected to the engaging slot 511 provided at the center shaft of the upper cover 51, and the outer end 551 of the spring 55 is engaged at the engaging slot 531 of the reeling disc 53 with an edge hook. When the reeling disc 53 rotates clockwise or anti-clockwise, the spring 55 becomes either taut or in loosen condition, and the tautening of the spring 55 provides the power for cable restoration of the cable reel 5.

The edge wall of the reeling disc 53 is a clipping plate 532 which can retract one end of the transmission cable 4 out from the clipping hole 533. The other end of the transmission cable 4 is retracted via a corresponding slit 534 so that the transmission cable 4 with equal length surrounds the upper and lower frame position at the outer edge of the reeling disc 53. When the transmission cable 4 is pulled from dual direction, the transmission cable 4 is pulled at the same time with the same speed, and the transmission cable 4 is further pulled, the transmission cable 4 will be restored to its original position.

The reeling disc 53 and the positioning member 57 at the inner edge of the lower cover 56 form an engaging and disengaging mechanism. The positioning member 57 includes a positioning shaft 571 and a positioning plate 572, and the positioning plate 572 covers the top section of the positioning shaft 571, and the two sides thereof is secured with a peg 570. The positioning plate 572 has a center pivot hole 5721 for pivotal mounting of a pivot 5711 on the positioning shaft 571 so that the positioning shaft 571 forms into a pivotal structure with the positioning plate 572. Additionally, the front end of the exposed positioning plate 572 is provided with a sliding protruded section 5712 corresponding to the railing slot 535 at the bottom section of the reeling disc 53.

The bottom section of the reeling disc 53 is provided with an operational railing slot 535 and the positioning shaft 571 provides an alternating engaging and disengaging action based on the rotating of the railing slot 535. Thus, when the transmission cable 4 is pulled, and the reeling disc 53 is rotating, the positioning shaft 571 together with the operational railing slot 535 forms into a swinging action. This swinging operation retracts the transmission cable 4 and then keeps the cable 4 in position. Another retracting of the transmission cable 4 causes the positioning shaft 571 to disengage. Another subsequent positioning is that after the positioning of the cable 4, before the cable 4 has fully retracted, another retraction of the cable 4 will cause the positioning shaft 571 to proceed to an engagement. Accordingly, the positioning shaft of a dual direction cable reel of the present invention provides a one-time reeling and multiple-stage reeling of cable positioning control.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A computer keyboard comprising:
a body portion;
two loudspeakers mounted on said body portion;
a microphone mounted on said body portion;
a plurality of sockets mounted on said body portion;
a switch mounted on said keyboard;
a volume control mounted on said keyboard;
a cable provided with a USB connector, a loudspeaker connector, a microphone connector; and
a cable reel connected with said cable, said cable reel comprising an upper cover, a pad, a reeling disc, a spring, and a lower cover, said reeling disc and a positioning element being mounted at an inner edge of said lower cover to form an engaging and disengaging mechanism, wherein said positioning element includes a positioning shaft and a positioning plate and said positioning plate covers a top portion of said positioning shaft and is secured with a peg and said positioning plate has a pivot hole at a center thereof for a pivot mounting of said positioning shaft, and a front end of said positioning plate exposed from a shaft body of a positioning shaft is provided with a sliding protruded section corresponding to a railing slot at a bottom section of said reeling disc, and a bottom section is provided with a railing slot for said sliding protruded section to rotate along said reeling slot so as to provide an alternating engaging and a disengaging action.

2. The computer keyboard as claimed in claim 1, wherein said loudspeakers are arranged on two sides of a top of said body portion.

3. The computer keyboard as claimed in claim 1, wherein said microphone is mounted at a front side portion of said body portion.

4. The computer keyboard as claimed in claim 1, wherein said cable has a USB connector, a loudspeaker connector and a microphone connector.
